(19) United States
(12) Patent Application Publication
(10) Pub. No.: US 2010/0248164 A1
(43) Pub. Date: Sep. 30, 2010

(54) CLEANING LIQUID FOR LITHOGRAPHY AND METHOD FOR FORMING A RESIST PATTERN USING THE SAME

(75) Inventors: Tomoya KUMAGAI, Kawasaki-shi (JP); Masahiro MASUJIMA, Kawasaki-shi (JP); Jun KOSHIYAMA, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/730,087

(22) Filed: Mar. 23, 2010

(30) Foreign Application Priority Data
Mar. 31, 2009 (JP) 2009-088527
Nov. 20, 2009 (JP) 2009-265213

(51) Int. Cl. G03F 7/20; C11D 1/02; C11D 1/12

(52) U.S. Cl. 430/325; 510/176

(57) ABSTRACT

Provided are a cleaning liquid for lithography capable of suppressing occurrence of CD shift without inhibiting the effect of preventing pattern collapse by a surfactant, and a pattern formation method using the cleaning liquid for lithography. A cleaning liquid for lithography containing (A) an anionic surfactant, (B) an amine compound, and (C) water. In the cleaning liquid for lithography of the present invention, the anionic surfactant and the amine compound form a salt in the cleaning liquid for lithography, and thus penetration of the anionic surfactant into a resist film can be suppressed. Therefore, even when a method for forming a resist pattern is performed, the resist film is not dissolved by using the cleaning liquid for lithography of the present invention, whereby occurrence of CD shift can be efficiently suppressed.

This application is based on and claims the benefit of priority from Japanese Patent Application Nos. 2009-088527 and 2009-265213, respectively filed on 31 Mar. 2009 and 20 Nov. 2009, the contents of which are incorporated herein by reference.

### BACKGROUND OF THE INVENTION

1. Field of the Invention

The present invention relates to a cleaning liquid for lithography, and a method for forming a resist pattern using the same.

2. Related Art

In recent years, along with size reduction and integration of semiconductor devices, resist materials used in manufacturing semiconductor devices have been improved so as to be capable of meeting such size reduction and integration. However, as size reduction and integration of semiconductor devices have further progressed, issues concerning defects have become a great concern.

Defects mean errors of a resist pattern after development not consistent with the mask pattern (unfavorable resist pattern, scum, dust, uneven color, fusion among patterns and the like) detected upon observation of the resist pattern from directly above with a surface defect observation instrument. Here, since a larger number of defects results in yield loss, mass production of semiconductor elements can be hampered unless the issues concerning such defects are resolved even though superior resist characteristics are achieved. Various causes of the defects have been suggested, and some of such causes result from microbubbles generated during development, and readhesion of insoluble matter which was once eliminated by cleaning.

Problems which should be necessarily solved involve such issues concerning defects, and collapse of resist patterns which are peculiar to formation of recent ultraminiaturized resist patterns having a high aspect ratio. It is reported that the collapse of the resist pattern occurs due to the surface tension generated during drying of the cleaning liquid for lithography.

Under such circumstances, cleaning liquids for lithography prepared by dissolving a surfactant in water have been proposed. By using such a cleaning liquid for lithography, surface tension can be lowered, and as a result, the stress between patterns generated during spin drying of the cleaning liquid for lithography can be reduced, whereby suppression of pattern collapse is enabled (see, Patent Documents 1 to 3). In addition, a surfactant having both a hydrophilic group and a hydrophobic group adsorbs to the resist surface and the surface of insoluble matters which had been already eliminated, and thus readhesion of such insoluble matters to the resist surface can be prevented by electrostatic repulsive force.

Patent Document 1: Japanese Unexamined Patent Application No. 2007-213013

Patent Document 2: Japanese Unexamined Patent Application No. 2007-025392

Patent Document 3: Japanese Unexamined Patent Application No. 2006-189755

### SUMMARY OF THE INVENTION

However, when a cleaning liquid containing a surfactant is used for lithography, the resist surface is swollen or dissolved although the extent of these events may vary. Therefore, when compared with the case in which pure water is used, CD shift may occur in connection with swelling of the resist leading to thickening, as well as dissolution of the resist pattern to result in thinning, and the like.

The present invention was made in view of the foregoing problems, and an object of the invention is to provide a cleaning liquid for lithography that suppresses occurrence of CD shift without inhibiting the effect of preventing pattern collapse by a surfactant, and a pattern formation method using this cleaning liquid for lithography.

The present inventors found that when a cleaning liquid for lithography containing (A) an anionic surfactant, (B) an amine compound and (C) water is used, occurrence of CD shift can be suppressed without inhibiting the effect of preventing pattern collapse by a surfactant, and have completed the present invention.

Specifically, the present invention provides the following.

According to a first aspect of the present invention, a cleaning liquid for lithography is provided which includes (A) an anionic surfactant, (B) an amine compound and (C) water.

According to a second aspect of the present invention, a cleaning liquid for lithography is provided which includes (A′) an anionic surfactant and (C) water, in which an anionic group of the anionic surfactant is forming a salt with (B) an amine compound.

According to a third aspect of the present invention, a method for forming a resist pattern is provided which is characterized by including the steps, which are carried out sequentially, of: providing a resist film on a substrate; selectively exposing the resist film through a mask pattern; subjecting the exposed resist film to post exposure heating; forming a resist pattern by developing the resist film with alkali following the post-exposure baking; and allowing the resist pattern to be in contact with the cleaning liquid for lithography of the present invention.

According to the present invention, since an anionic surfactant and an amine compound are contained in a cleaning liquid for lithography, the anionic surfactant and the amine compound form a salt in the cleaning liquid for lithography, and thus penetration of the anionic surfactant into a resist film can be suppressed. Therefore, when a method for forming a resist pattern is performed using the cleaning liquid for lithography of the present invention, the resist film is not dissolved, whereby occurrence of CD shift can be efficiently suppressed.

### DETAILED DESCRIPTION OF THE INVENTION

Hereinafter, embodiments of the present invention will be explained in detail.

### Cleaning Liquid for Lithography

The cleaning liquid for lithography of the present invention contains (A) an anionic surfactant, (B) an amine compound and (C) water.

### Anionic Surfactants (A) and (A′)

When an anionic surfactant is added to a cleaning liquid for lithography, the surface tension of the cleaning liquid for lithography can be lowered, and thus the stress between patterns generated, for example, when the cleaning liquid for lithography is spin dried can be lowered. Accordingly, pattern collapse can be suppressed by performing a method for forming a resist pattern using the cleaning liquid for lithography containing an anionic surfactant.

The anionic surfactant which may be contained in the cleaning liquid for lithography of the present invention is not particularly limited, and a conventionally well-known surfactant having an anionic group can be used. Examples of such anionic surfactants include surfactants having a carboxylic acid group, a sulfonic acid group, or a phosphoric acid group as an anionic group.

Specifically, higher fatty acids having an alkyl group having 8 to 20 carbon atoms, higher alkyl sulfuric acid esters, higher alkyl sulfonic acids, higher alkylaryl sulfonic acids, other surfactants having a sulfonic acid group, and higher alcohol phosphoric acid esters, salts thereof, and the like may be exemplified. Wherein, the alkyl group of the anionic surfactant may be either linear or branched, and a phenylene group, an oxygen atom or the like may be present in the molecular chain, or a part of the hydrogen atoms in the alkyl group may be substituted with a hydroxy group or a carboxyl group.

Specific examples of the higher fatty acid include dodecanoic acid, tetradecanoic acid, stearic acid and the like, and specific examples of the higher alkyl sulfuric acid ester include decylsulfuric acid esters and dodecyl sulfuric acid esters and the like. Furthermore, examples of the higher alkyl sulfonic acid include decane sulfonic acid, dodecane sulfonic acid, tetradecane sulfonic acid, pentadecane sulfonic acid, stearate sulfonic acid, and the like.

In addition, specific examples of the higher alkylaryl sulfonic acid include dodecylbenzene sulfonic acid, decylnaphthalene sulfonic acid, and the like.

Moreover, the other surfactant having a sulfonic acid group may be exemplified by alkyldiphenyl ether disulfonic acid such as dodecyldiphenyl ether disulfonic acid, as well as dialkyl sulfosuccinate such as dioctyl sulfosuccinate, and the like.

Examples of the higher alcohol phosphoric acid ester include, palmityl phosphoric acid esters, castor oil alkyl phosphoric acid esters, and coconut oil alkyl phosphoric acid esters, and the like.

Among the anionic surfactants described above, surfactants having a sulfonic acid group are preferably used, and specific examples thereof include alkyl sulfonic acid, alkylbenzene sulfonic acid, olefin sulfonic acid, alkyldiphenyl ether disulfonic acid, alkylnaphthalene sulfonic acid, dialkyl sulfosuccinate, and the like. Among these, alkyl sulfonic acid, alkylbenzene sulfonic acid, alkyldiphenyl ether disulfonic acid, and dialkyl sulfosuccinate are preferably used. The average carbon number of the alkyl group of the alkyl sulfonic acid is preferably 9 to 21, and more preferably 12 to 18. Moreover, the average carbon number of the alkyl group of the alkylbenzene sulfonic acid is preferably 6 to 18, and more preferably 9 to 15. The average carbon number of the alkyl group of the alkyldiphenyl ether disulfonic acid is preferably 6 to 18, and more preferably 9 to 15. Still further, the average carbon number of the alkyl group of dialkyl sulfosuccinate is preferably 4 to 12, and more preferably 6 to 10.

Among the foregoing anionic surfactants, alkyl sulfonic acid having an alkyl group having an average carbon number of 15, and alkylbenzene sulfonic acid having an alkyl group having an average carbon number of 12 are preferably used.

It is to be noted that although the cleaning liquid for lithography of the present invention contains an amine compound described later in addition to the aforementioned anionic surfactant (A), the cleaning liquid for lithography may be prepared by separately adding the anionic surfactant and the amine compound, or an anionic surfactant described later in which the anionic group forms a salt with an amine compound may be contained as an anionic surfactant (A′) without adding the amine compound.

Specific examples of the anionic surfactant (A′) in which the anionic group forms a salt with an amine compound include monoethanolamine salts, diethanolamine salts, tetramethylammonium salts and tetraethylammonium salts of alkyl sulfonic acid having an alkyl group having an average carbon number of 9 to 21; and monoethanolamine salts, diethanolamine salts, tetramethylammonium salts and tetraethylammonium salts of alkylbenzene sulfonic acid having an alkyl group having an average carbon number of 6 to 18. Of these, salts of alkyl sulfonic acid having an alkyl group having an average carbon number of 15 and an amine compound, and salts of a tetramethylammonium salt and monoethanolamine are preferred, and further, salts of a tetramethylammonium salt and monoethanolamine are more preferred.

The anionic surfactants described above may be used alone, or two or more may be used as a mixture.

The content of the anionic surfactant is preferably no lower than and 100 ppm and no higher than 1% by mass, and more preferably 500 ppm to 5,000 ppm. When the content of the anionic surfactant is no lower than 100 ppm, the surface tension of the cleaning liquid for lithography can be sufficiently lowered, and thus the pattern collapse can be efficiently suppressed. When the content of the anionic surfactant is no higher than 1% by mass, dissolution of the resist pattern by the cleaning liquid for lithography can be further suppressed, and CD shift can be further suppressed.

### Amine Compound (B)

The cleaning liquid for lithography of the present invention contains an amine compound. By including an amine compound in the cleaning liquid for lithography, a salt is formed with the anionic surfactant, and thus penetration of the anionic surfactant into the resist film can be suppressed. Accordingly, dissolution of the resist pattern can be suppressed, and CD shift can be also suppressed.

The amine compound which may be used in the cleaning liquid for lithography of the present invention is not particularly limited, and any amine compound having water solubility can be utilized. In the present invention, for example, alkanolamines and alkylalkanolamines having an alkylene chain or an alkyl group having 2 to 5 carbon atoms, and quaternary amine compounds such as quaternary ammonium hydroxides and quaternary ammonium halides may be exemplified. In addition, the amine compound is also exemplified by NH₃ (aqueous ammonia).

Specifically, the alkanolamines include monoethanolamine, diethanolamine, and triethanolamine; and the alkylalkanolamines include ethylmonoethanolamine, butylmonoethanolamine, dimethylethanolamine, diethylethanolamine, ethyldiethanolamine, butyldiethanolamine, and dibutylethanolamine.

In addition, the quaternary amine compounds are exemplified by quaternary ammonium hydroxides, quaternary ammonium halides and the like, and the quaternary ammonium hydroxides are preferred. Among the quaternary ammonium hydroxides, quaternary ammonium hydroxides having an alkyl group or an alkenyl group having 4 to 24 carbon atoms in total are preferred. The alkyl group includes a methyl group, an ethyl group, a linear or branched propyl group, a linear or branched butyl group, a linear or branched pentyl group, or a linear or branched hexyl group. In addition, the alkenyl group includes an ethylene group, a linear or branched propylene group, a linear or branched butylene group, a linear or branched pentenyl group, or a linear or branched hexenyl group. Hydroxides of such quaternary ammonium may include up to four groups selected from the aforementioned alkyl groups and alkylene groups in any combination. Examples of such quaternary ammonium hydroxides include tetramethylammonium hydroxide, tetraethylammonium hydroxide, 2-hydroxyethyltrimethylammonium hydroxide, tetrapropylammonium hydroxide, methyltripropylammonium hydroxide, tetrabutylammonium hydroxide, tetrapentylammonium hydroxide, and methyltributylammonium hydroxide. Of these, tetramethylammonium hydroxide, tetraethylammonium hydroxide, tetrapropylammonium hydroxide, tetrabutylammonium hydroxide, or tetrapentylammonium hydroxide is preferred, and tetramethylammonium hydroxide, or tetraethylammonium hydroxide is particularly preferred.

Among the foregoing amine compounds, NH₃ (aqueous ammonia), monoethanolamine, tetramethylammonium hydroxide, diethanolamine, and triethanolamine are preferred, and NH₃ (aqueous ammonia), monoethanolamine, and tetramethylammonium hydroxide are more preferred.

The content of the amine compound in the cleaning liquid for lithography of the present invention is preferably no lower than 100 ppm and no higher than 1% by mass, and more preferably no lower than 500 ppm and no higher than 5,000 ppm, relative to the entire cleaning liquid for lithography. Moreover, the content ratio of the anionic surfactant to the amine compound is preferably from 50:1 (i.e. 98.04:1.96) to 1:10 (i.e. 9.1:90.9). This content ratio is more preferably 98:2 to 10:90, still more preferably 97.5:2.5 to 50:50, and particularly preferably 97.3:2.7 to 75:25. When the content ratio of the anionic surfactant and the amine compound falls within the above range, the balance of the contents of the anionic surfactant and the amine compound can be kept at a favorable level, and thus the salt of the anionic surfactant and the amine compound becomes more likely to be formed, whereby the effect of suppressing CD shift can be further improved.

### Water (C)

The cleaning liquid for lithography of the present invention contains water. The content of water is preferably no lower than 90% by mass and no higher than 99.99% by mass, and more preferably no lower than 95% by mass and no higher than 99.95% by mass.

In the cleaning liquid for lithography of the present invention, a mixed solvent including water and an organic solvent miscible with water can be used as a solvent in addition to water, as desired. The organic solvent miscible with water which may be used for this purpose is exemplified by monohydric alcohol or polyhydric alcohol.

Examples of the aforementioned monohydric alcohol include methanol, ethanol, and propanol, and examples of the polyhydric alcohol include ethylene glycol, propylene glycol, diethylene glycol, glycerin, and alkyl etherified products and esterified products of these. The proportion of these organic solvents miscible with water contained may be determined in the range of usually no less than 0.01% by mass and no greater than 10% by mass, and preferably no less than 0.1% by mass and no greater than 5% by mass, based on the total mass of the mixed solvent.

In the cleaning liquid for lithography of the present invention, by using such a mixed solvent of water and the organic solvent miscible with water as described above, the cleaning liquid for lithography can be diffused on the surface of the wafer efficiently in processing the wafer.

### Method for Forming Resist Patterns

In the method for forming a resist pattern of the present invention, the steps of: providing a resist film on a substrate (step (1)); selectively exposing the resist film through a mask pattern (step (2)); subjecting the exposed resist film to post-exposure baking (step (3)); forming a resist pattern by developing the resist film with alkali following the post-exposure baking (step (4)); and allowing the resist pattern to be in contact with the cleaning liquid for lithography of the present invention (step (5)) are carried out sequentially.

In the step (1), a resist film is provided on a substrate. As the substrate, a silicon wafer is generally used. In the method for forming a resist pattern, when a silicon wafer having a large diameter is used in particular, problems of resist pattern collapse and generation of defects have become marked. However, according to the method for forming a resist pattern performed using the cleaning liquid for lithography of the present invention, resist pattern collapse can be prevented even when a silicon wafer of no less than 8 inches or no less than 12 inches is used in the step (1).

As the resist composition for forming a resist film, conventionally known one can be used. In the method for forming a resist pattern of the present invention, resist pattern collapse can be efficiently prevented even when a fine resist pattern is formed using a resist corresponding to KrF excimer laser (248 nm) or a resist corresponding to EB that contains a hydroxystyrene based resin, a resist corresponding to ArF excimer laser (193 nm) that contains an acrylic resin or a cycloolefin based resin, or the like as the resist composition.

In addition, according to the method for forming a resist pattern of the present invention, problems of resist pattern collapse and generation of defects can be efficiently prevented even in the case in which a fine resist pattern having a high aspect ratio is formed by a liquid immersion lithography process which has attracted attention as current and future lithography. Therefore, a resist composition for use in liquid immersion lithography processes, and the like can be suitably used in the aforementioned step (1).

It is to be noted that when a resist film is formed on a substrate such as a silicon wafer in the step (1), the resist composition may be applied with a spinner or the like and then dried.

In the step (2), the resist film formed in the step (1) is selectively exposed through a mask pattern to form a latent image, and the exposed resist film is subjected to a post-exposure baking in the following step (3). These step (2) and step (3) can be carried out similarly to those of the method for forming a resist pattern in which a conventional resist is used.

The resist film following the post-exposure baking via the step (3) is subjected to alkali development in the step (4) to form a resist pattern. The aforementioned alkali development is carried out using, for example, an aqueous tetramethylammonium hydroxide solution of no less than 1% by mass and no greater than 10% by mass, and preferably 2.38% by mass.

In the method for forming a resist pattern of the present invention, the resist pattern is brought into contact with the cleaning liquid for lithography of the present invention, after the step (4) (step (5)).

In the step (5), a time period of allowing the resist pattern to be in contact with the cleaning liquid for lithography may be determined appropriately depending on the conditions in which the method for forming a resist pattern of the present invention is applied. For example, when a semiconductor element is produced, high throughput will be a significant requirement for mass production; therefore, the time period of the step (5) is preferably as short as possible. Specifically, the time period is selected appropriately in the range of no shorter than 1 sec and no longer than 180 sec.

When the resist pattern is allowed to be in contact with the cleaning liquid for lithography in the step (5), for example, the cleaning liquid for lithography is applied to or spread on the resist pattern surface, or the resist pattern is immersed in the cleaning liquid for lithography. The time period of allowing the resist pattern to be in contact with the cleaning liquid for lithography is preferably no shorter than 1 sec and no longer than 30 sec.

In the method for forming a resist pattern of the present invention, a step of rinsing with pure water may be added if desired, prior to the step (5) of allowing the resist pattern to be in contact with the cleaning liquid for lithography.

When a resist pattern is formed by a common method for forming a resist pattern, alkali insoluble matter in the resist film may be separated out during rinsing with pure water after the alkali development, and adhere to the resist pattern, leading to causes of generation of defects. However, in the method for forming a resist pattern of the present invention, the surface of the resist pattern can be maintained as hydrophilic by treating the resist pattern with the cleaning liquid for lithography of the present invention in the step (5); therefore, readhesion of the alkali insoluble matter in the resist film to the surface of the resist pattern can be prevented. Accordingly, generation of the defects can be suppressed efficiently.

In addition, since the cleaning liquid for lithography of the present invention contains an anionic surfactant, elevation of the stress between the patterns can be avoided even in drying the cleaning liquid for lithography which had been brought into contact with the resist pattern in the step (5), and thus collapse of the resist pattern can be efficiently suppressed. Moreover, since an amine compound is contained in addition to the anionic surfactant, the anionic surfactant and the amine compound form a salt in the cleaning liquid for lithography, whereby penetration of the anionic surfactant into the resist film can be suppressed. Therefore, even when a method for forming a resist pattern is performed, occurrence of CD shift can be efficiently suppressed without dissolving the resist film by using the cleaning liquid for lithography of the present invention, and the exposure limit and the exposure latitude margin are not deteriorated even in comparison with the case when rinsed with pure water, and also pattern line width roughness can be improved.

### EXAMPLES

Hereinafter, the present invention will be explained in detail by way of Examples. The present invention is not in anyway limited to the Examples demonstrated in the following. Evaluation of Cleaning Liquid for Lithography (1)

### Example 1

A cleaning liquid for lithography was prepared by adding a tetramethylammonium alkylsulfonate salt having a linear alkyl group having an average carbon number of 15 to pure water to give a content of 1,300 ppm.

### Example 2

A cleaning liquid for lithography was prepared in a similar manner to Example 1 except that a monoethanolamine alkylsulfonate salt having a linear alkyl group having an average carbon number of 15 was added in place of the tetramethylammonium alkylsulfonate salt having a linear alkyl group having an average carbon number of 15.

### Example 3

A cleaning liquid for lithography was prepared by adding alkylbenzene sulfonic acid having a linear alkyl group having an average carbon number of 12 to give a content of 1,000 ppm, and tetramethylammonium hydroxide to give a content of 200 ppm.

### Example 4

A cleaning liquid for lithography was prepared in a similar manner to Example 3 except that the amount of the tetramethylammonium hydroxide added was changed to give a content of 300 ppm.

### Example 5

A cleaning liquid for lithography was prepared in a similar manner to Example 3 except that monoethanolamine was added in place of the tetramethylammonium hydroxide to give a content of 150 ppm.

### Example 6

A cleaning liquid for lithography was prepared in a similar manner to Example 5 except that the amount of the monoethanolamine added was changed to give a content of 300 ppm.

### Comparative Example 1

A cleaning liquid for lithography was prepared by adding lauryldimethylamine oxide to pure water to give a content of 500 ppm.

### Comparative Example 2

A cleaning liquid for lithography was prepared in a similar manner to Example 3 except that tetramethylammonium hydroxide was not added.

### Evaluations

### Formation of Resist Film

An antireflection film having a film thickness of 89 nm was formed by applying a composition for forming an antireflection film “ARC-29A” on a 12-inch silicon wafer. An ArF resist composition “TArF-PP006” (product name, manufactured by Tokyo Ohka Kogyo Co., Ltd.) was applied on this antireflection film, and heated at 120° C. for 60 sec to form a resist film having a film thickness of 70 nm.

### Exposure

The formed resist film was subjected to an exposure treatment using an ArF liquid immersion lithography device “NSR-S609B” (product name, manufactured by Nikon Corporation) through a mask pattern of L/S being 50 nm, with an exposure dose of 5.0 mJ/cm² to 52.0 mJ/cm², and thereafter subjected to a heat treatment at 90° C. for 60 sec.

### Development and Cleaning

Next, after carrying out a development treatment using a 2.38% by mass aqueous tetramethylammonium hydroxide solution at 23° C. for 30 sec, deionized water (Reference Example 1), or the cleaning liquid for lithography of any one of Examples 1 to 6, and Comparative Examples 1 and 2 was applied on the resist pattern, while spinning at 1,200 rpm for 3 sec, then at 500 rpm for 4 sec, and thereafter spin dried at 2,000 rpm for 15 sec.

### Evaluation of CD Shift

By observation of the pattern width of the resulting resist pattern using a scanning electron microscope (SEM), a critical dimension (CD) was measured when cleaned with the cleaning liquid for lithography at an exposure dose (optimum exposure dose) that enables achieving a resist pattern dimension corresponding to a target dimension (50 nm) when cleaned with deionized water, and the difference between the critical dimensions measured when deionized water was used and when the cleaning liquid for lithography was used, whereby CD shift was determined. In addition, the rate (%) of the CD shift (absolute value) relative to the target dimension was also determined.

### Evaluation of Exposure Latitude Margin (EL Margin)

The pattern width of the resist pattern was observed using a scanning electron microscope (SEM), and the value range of the exposure dose enabling the formation with the pattern width falling within the range of ±5% of the target dimension was determined, and the rate (%) of the difference between the maximum value and minimum value of the range was calculated, with respect to the aforementioned optimum light exposure. It is to be noted that the EL margin means the exposure dose range that enables the resist pattern to be formed when exposed with varying exposures dose under conditions that yield the shift with respect to the target dimension in a predetermined range, i.e., means the range of light exposure that enables the resist pattern strictly reproducing the mask pattern to be obtained, and the greater EL margin value leads to an assessment as being more preferable.

### Evaluation of Line Width Roughness (LWR)

Using a scanning electron microscope (SEM), line widths of the resist pattern at the optimum exposure dose were measured at five points along the longitudinal direction of the line, and the value (3s) three times of the standard deviation (s) of the obtained values was determined as a measure representing LWR. Note that the smaller 3s value indicates less line width roughness, and reveals that a resist pattern having a further uniform line width could be formed.

### Evaluation of Collapse Latitude

The resist pattern was observed using a scanning electron microscope (SEM), and the rate (%) of the minimum light exposure at which the resist pattern collapsed was determined with respect to the optimum light exposure. Note that as this value is greater, the resist pattern is evaluated to be less likely to be collapsed, and such a greater value leads to an assessment as being more preferable.

The results in the foregoing are shown in Table 1.

TABLE 1

| | | | Exposure | | |
|---|---|---|---|---|---|
| | | | latitude | Line width | Collapse |
| | CD shift | CD shift | margin | roughness | latitude |
| | (nm) | (%) | (%) | (nm) | (%) |
| Example 1 | 1.22 | 2.44 | 8.75 | 4.95 | 161 |
| Example 2 | 0.99 | 1.98 | 9.35 | 4.99 | 165 |
| Example 3 | 0.46 | 0.92 | 10.08 | 5.20 | 166 |
| Example 4 | 3.42 | 6.84 | 8.71 | 4.66 | 160 |
| Example 5 | −1.31 | 2.62 | 8.00 | 4.90 | 171 |
| Example 6 | −1.57 | 3.14 | 8.37 | 4.95 | 172 |
| Comparative | −5.59 | 11.18 | 8.70 | 5.15 | 177 |
| Example 1 | | | | | |
| Comparative | −5.40 | 10.8 | 8.58 | 4.97 | 178 |
| Example 2 | | | | | |
| Reference | — | — | 8.08 | 5.52 | 156 |
| Example 1 | | | | | |

As is clear from Table 1, when a method for forming a resist pattern was performed using the cleaning liquid for lithography of the present invention, the CD shift could be suppressed at a low level while sufficiently suppressing the resist pattern collapse. Such results are in contrast to those of Comparative Examples 1 and 2 indicating great CD shift although the resist pattern collapse could be suppressed. In addition, when a method for forming a resist pattern was performed using the cleaning liquid for lithography of the present invention, the line width roughness of the pattern could also be improved without resulting in deterioration of the exposure latitude margin even in comparison with the case when rinsed with pure water.

### Evaluation of Cleaning Liquid for Lithography (2)

### Preparation of Cleaning Liquid for Lithography

Cleaning liquids for lithography were prepared to give the concentration of each component in pure water shown by each value in parentheses of [ ] in Table 2.

TABLE 2

| | Anionic surfactant | Amine compound |
|---|---|---|
| Example 7 | sulfonic acid (1) | amine (1) |
| | [1300 ppm] | [200 ppm] |
| Example 8 | sulfonic acid (1) | amine (1) |
| | [1300 ppm] | [135 ppm] |
| Example 9 | sulfonic acid (1) | amine (1) |
| | [1300 ppm] | [90 ppm] |
| Example 10 | sulfonic acid (1) | amine (1) |
| | [1300 ppm] | [40 ppm] |
| Example 11 | sulfonic acid (1) | amine (2) |
| | [1300 ppm] | [75 ppm] |

sulfonic acid (1): alkylbenzene sulfonic acid having a linear alkyl group having an average carbon number of 12
amine (1): monoethanolamine
amine (2): NH₃

### Preparation of ArF Resist Composition

### Synthesis of Polymer Compound

In a three-neck flask equipped with a thermometer and a reflux condenser, 7.85 g (46.16 mmol) of compound (1), 10.00 g (31.65 mmol) of compound (2), 8.50 g (34.29 mmol) of compound (3), 3.10 g (18.46 mmol) of compound (4), and 2.18 g (9.23 mmol) of compound (5) were dissolved in 47.45 g of methyl ethyl ketone (MEK). To this solution was added 14.0 mmol of dimethyl azobisisobutyrate (V-601) as a polymerization initiator and dissolved. This solution was added dropwise over 3 hrs under a nitrogen atmosphere to MEK (26.35 g) heated to 78° C. After completing the dropwise addition, the reaction mixture was heated while stirring for four hrs, and thereafter cooled to room temperature. The resulting reaction mixture was subjected to a procedure for allowing the polymer to be separated out by adding dropwise to a large quantity of n-heptane, and the precipitated white powder was filtered off and washed with a mixed solvent of n-heptane/isopropyl alcohol, followed by drying to obtain 21 g of intended polymer compound (6). The reaction formula is shown below.

With regard to this polymer compound (6), the mass average molecular weight (Mw) equivalent to standard polystyrene determined by GPC measurement was 7,600, and the molecular weight dispersity (Mw/Mn) was 1.54. In addition, copolymerization composition ratio (ratio of each constituent unit (molar ratio) in the formula) determined by a carbon 13 nuclear magnetic resonance spectrum (600 MHz, ¹³C-NMR) was l/m/n/o/p=34.9/26.0/19.0/12.6/7.5.

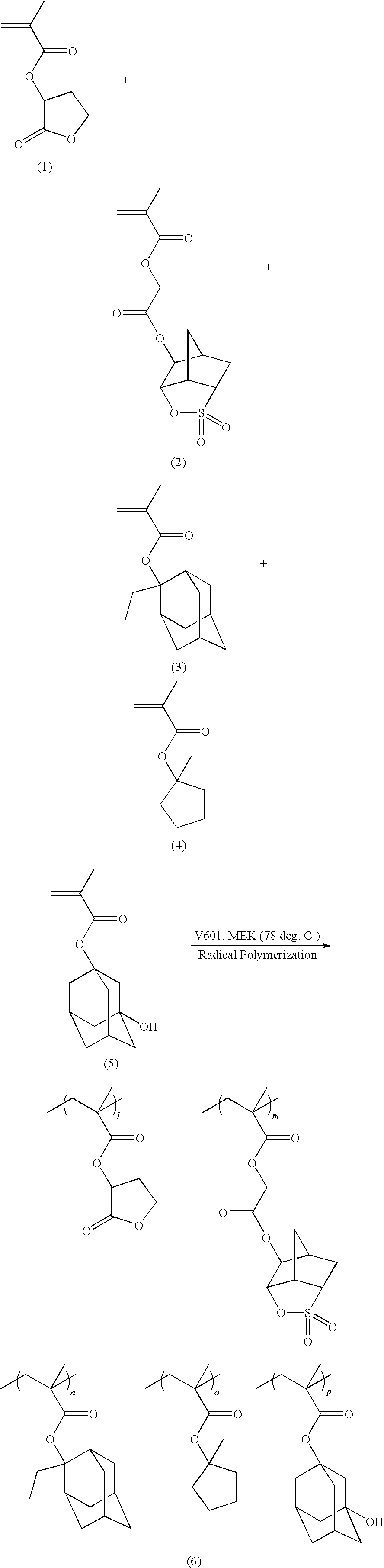

Note that the compound (2) described above was synthesized as in the following.

To a 500-ml three-neck flask were charged under a nitrogen atmosphere, 20 g (105.14 mmol) of alcohol (8), 30.23 g (157.71 mmol) of ethyldiisopropylaminocarbodiimide (EDCI) hydrochloride, and 300 ml of a solution of 0.6 g (5 mmol) of dimethylaminopyridine (DMAP) in THF. Thereto was added 16.67 g (115.66 mmol) of precursor (7), and stirred at room temperature for 12 hrs. After ascertaining disappearance of the starting material on a thin layer chromatography (TLC), 50 ml of water was added to stop the reaction. The reaction solvent was concentrated under reduced pressure, and extracted three times with ethyl acetate. Thus obtained organic layer was washed with water, saturated sodium hydrogencarbonate, and 1 N aqueous HCl in this order. The product obtained by distilling off the solvent under reduced pressure was dried to obtain the compound (2). The reaction equation is shown below.

The results of instrumental analysis of the obtained compound (2) were as follows.

¹H-NMR (CDCl₃, 400 MHz): δ (ppm)=6.22 (s, 1H, H^{a}), 5.70 (s, 1H, H^{b}), 4.71-4.85 (m, 2H, H^{c,d}), 4.67 (s, 2H, H^{k}), 3.40-3.60 (m, 2H, H^{e,f}), 2.58-2.70 (m, 1H, H^{g}), 2.11-2.21 (m, 2H, H^{h}), 2.00 (s, 3H, Hⁱ), 1.76-2.09 (m, 2H, H^{j}).

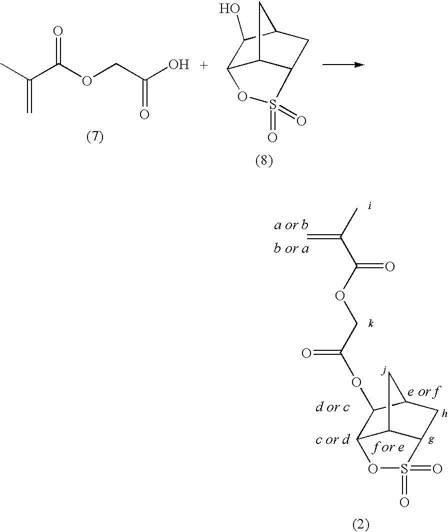

### Preparation of ArF Resist Composition

In 2,900 parts by mass of a mixed solvent of propylene glycol monomethyl ether acetate/propylene glycol monomethyl ether=6/4 (mass ratio) were dissolved and mixed 100 parts by mass of the polymer compound (6) synthesized as described above, 11.4 parts by mass of the acid generator (9) represented by the following formula, 2 parts by mass of triphenylsulfonium d-camphor-10-sulfonate, 0.21 parts by mass of salicylic acid, 25 parts by mass of gamma-butyrolactone, and 1.5 parts by mass of polymer compound (10) represented by the following formula (mass average molecular weight (Mw): 7,600, molecular weight dispersity (Mw/Mn): 1.54, f1/f2=78/22 (molar ratio)) to prepare a positive ArF resist composition.

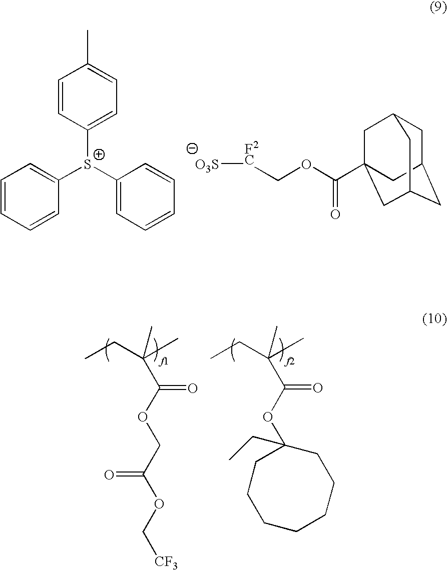

### Evaluation

### Formation of Resist Film

An antireflection film having a film thickness of 85 nm was formed by applying a composition for forming an antireflection film “ARC-29A” on a 12-inch silicon wafer. The ArF resist composition prepared as described above was applied on this antireflection film, and heated at 120° C. for 60 sec to form a resist film having a film thickness of 100 nm.

### Exposure

The formed resist film was subjected to an exposure treatment using an ArF exposure device “NSR-S308F” (product name, manufactured by Nikon Corporation) through a mask pattern of L/S being 60 nm, with several optimum light exposures (Eop), and thereafter subjected to a heat treatment at 90° C. for 60 sec.

### Development and Cleaning

Next, after carrying out a development treatment using a 2.38% by mass aqueous tetramethylammonium hydroxide solution at 23° C. for 30 sec, deionized water (Reference Example 2), or the cleaning liquid for lithography of any one of Examples 7 to 11 was applied on the resist pattern, while spinning at 1,200 rpm for 3 sec, then at 500 rpm for 7 sec (however, at 500 rpm for 12 sec in Reference Example 2), and thereafter spin dried at 2,000 rpm for 15 sec.

With regard to thus obtained resist pattern, “Evaluation of CD Shift”, “Evaluation of Line Width Roughness (LWR)”, and “Evaluation of Collapse Latitude” were made similarly to Examples 1 to 6 and the like as described above. The results are shown in Table 3.

TABLE 3

| | | | | Line width | Collapse |
|---|---|---|---|---|---|
| | Eop | CD shift | CD shift | roughness | latitude |
| | (mJ/cm²) | (nm) | (%) | (nm) | (%) |
| Example 7 | 24.2 | 5.7 | 9.50 | 4.18 | 178 |
| Example 8 | 23.4 | 2.8 | 4.67 | 4.32 | 192 |
| Example 9 | 22.5 | 0.4 | 0.67 | 3.70 | 200 |
| Example 10 | 22.2 | −0.4 | 0.67 | 4.11 | 207 |
| Example 11 | 24.9 | 6.3 | 10.50 | 4.30 | 175 |
| Reference | 22.5 | — | — | 4.45 | 173 |
| Example 2 | | | | | |

As is clear from Table 3, when a method for forming a resist pattern was performed using the cleaning liquid for lithography of the present invention, the line width roughness of the pattern could be improved while keeping the CD shift at a level of no greater than about 10%, and the resist pattern collapse could be suppressed in comparison with the case when rinsed with pure water.

What is claimed is:

1. A cleaning liquid for lithography comprising (A) an anionic surfactant, (B) an amine compound, and (C) water.

2. The cleaning liquid for lithography according to claim 1, wherein the content ratio of the anionic surfactant to the amine compound is from 50:1 to 1:10.

3. A cleaning liquid for lithography comprising (A′) an anionic surfactant and (C) water, wherein
an anionic group of the anionic surfactant forms a salt with (B) an amine compound.

4. The cleaning liquid for lithography according to claim 1, wherein the anionic surfactant has a sulfonic acid group as an anionic group.

5. The cleaning liquid for lithography according to claim 1, wherein the content of the anionic surfactant is no less than 100 ppm and no greater than 1% by mass.

6. A method for forming a resist pattern comprising the steps, which are carried out sequentially, of: providing a resist film on a substrate;
selectively exposing the resist film through a mask pattern;
subjecting the exposed resist film to post-exposure baking;
forming a resist pattern by developing the resist film with alkali following the post-exposure baking; and
allowing the resist pattern to be in contact with the cleaning liquid for lithography according to claim 1.
